(19) United States
(12) Patent Application Publication
(10) Pub. No.: US 2010/0020311 A1
(43) Pub. Date: Jan. 28, 2010

(54) Integrated quartz biological sensor and method

(75) Inventors: Deborah Janice Kirby, Calabasas, CA (US); Randall Lynn Kubena, Oakpark, CA (US)

Correspondence Address: LADAS & PARRY, 5670 WILSHIRE BOULEVARD, SUITE 2100, LOS ANGELES, CA, 90036-5679, US

(73) Assignee: HRL Laboratories, LLC

(21) Appl. No.: 11/818,797

(22) Filed: Jun. 14, 2007

(51) Int. Cl. G01N 21/65; G01N 21/84; H01L 21/50

(52) U.S. Cl. 356/72; 356/301; 438/25; 257/E21.499; 257/E33.076

(57) ABSTRACT

The present disclosure relates to the integration of optical spectroscopy onto a nanoresonator for a sensitive means of selectively monitoring biological molecules. An apparatus and a method are provided for making an apparatus that is a sensor in which both mass detection using a quartz nanoresonator and optical detection using SERS is integrated onto at least one chip, thereby providing redundancy in detection of a species.

### CROSS REFERENCE TO RELATED APPLICATIONS

This application may be related to U.S. patent application Ser. No. 10/426,931 titled “Quartz-Based Nanoresonators and Methods of Making Same” filed on Apr. 30, 2003; U.S. Pat. No. 6,933,164 titled “Method of Fabrication of a Micro-Channel Based Integrated Sensor For Chemical and Biological Materials” issued on Aug. 23, 2005 and U.S. Pat. No. 6,514,767 titled “Surface Enhanced Spectroscopy Active Composite Nanoparticles” issued on Feb. 4, 2003, all of which are incorporated by reference in their entirety.

### STATEMENT OF GOVERNMENT SUPPORT

The invention described herein was made under government contract DAABO7-02-C-P613, NMASP Nanoresonator sensor seedling awarded by DARPA MTO. The United States Government has certain rights in the invention.

### BACKGROUND

1. Field

The present disclosure relates to the integration of optical spectroscopy onto a nanoresonator for a sensitive means of selectively monitoring biological molecules.

2. Description of Related Art

The need for detection of biological agents in a variety of applications is acute. The rapid detection of very small quantities of harmful molecules, DNA, viruses, etc. using cheap throw-away sensors is particularly important.

A number of methods have been developed which allow such detection. Microelectromechanical (MEMS) technology possesses a major role in this field since MEMS sensors can be batch-processed for low cost and are capable of handling and detecting very small quantities of unknown substances. Small amounts of materials, often in the range of pico or femto liters, can be handled and measured.

Nanoresonators and microresonators are resonators which have linear dimensions on the order of nanometers and micrometers, respectively. These silicon-based nanoresonators have shown resonant frequencies as high as 600 MHz, and Q's in the range of 1000-2000.

Kubena et al (U.S. patent application Ser. No. 10/426,931—incorporated herein by reference in its entirety) disclose a method for fabricating and integrating quartz-based resonators on a high speed substrate for integrated signal processing by utilizing a combination of novel bonding and etching steps to form ultra thin quartz based resonators having the desired resonant frequency in excess of 100 MHz.

Raman spectroscopy is commonly used to identify functional groups in a molecule. Surface enhanced raman spectroscopy (SERS) provides enhanced detection capability permitting picomolar detection levels of chemical and biological species. In general, Raman spectroscopy provides real time detection of molecules in a non-contact mode, thereby avoiding sample contamination.

Natan (U.S. Pat. No. 6,514,767 and U.S. Ser. No. 11/132,471—both of which are incorporated herein by reference in their entirety) disclose a method for increasing the sensitivity of SERS for detection of known species for which metal nanoparticle “tags” (nanotags) can be made and used.

For the detection of biological species, sensors in the prior art which may be selective, are not sensitive enough to monitor the presence of picomolar or nanomolar levels of a given species. And, highly sensitive sensors are not selective enough to discriminate at the molecular level, which is needed to differentiate various strains of bacteria. It is desired to have a small, easy to use sensor for which the occurrence of “false positives” is rare. There is a need for a biological sensor having both high selectivity and high sensitivity which can be easily used for monitoring biological species.

### SUMMARY

The present disclosure describes an apparatus and a method for making an apparatus that is a sensor in which both mass detection using a quartz nanoresonator and optical detection using SERS is integrated onto at least one chip, thereby providing redundancy in detection of a biological species.

According to a first embodiment of the present disclosure, an apparatus is provided comprising: a mass detector disposed within a cavity to detect a sample; and an optical Surface Enhanced Raman Spectroscopy (SERS) detector disposed within said cavity to detect said sample.

According to a second embodiment of the present disclosure, an apparatus is provided for detection and analysis of biological species comprising at least two silicon wafers, wherein the at least two silicon wafers comprise a mass detector and an optical Surface Enhanced Raman Spectroscopy (SERS) detector, wherein the optical SERS detector comprises: a vertical cavity surface emitting laser (VCSEL), wherein the VCSEL is comprised of a lower metal contact, a first distributed Bragg reflector (DBR), an active layer comprised of one or more quantum wells, a second DBR and an upper metal contact; the apparatus further comprising an integrated beamsplitter and lens assembly coated with a dichroic filter, wherein the dichroic filter is comprised of thin films of varying refractive indices, a diffraction grating, and a detector array coated with a holographically formed filter.

According to a third embodiment of the present disclosure, a method for fabricating an apparatus is provided, comprising: providing a mass detector; an optical Surface Enhanced Raman Spectroscopy (SERS) detector; a first cavity, and a second cavity, wherein disposed on the first cavity is the mass detector for analyzing a molecule and disposed on the first and second cavity is the optical SERS detector for analyzing said molecule.

According to a fourth embodiment of the present disclosure, a method for fabricating a sensor is provided, comprising the steps of: providing a quartz substrate; providing at least one electrode and at least one tuning pad to the quartz substrate; providing a silicon handle wafer having a cavity etched therein; bonding the silicon handle wafer to the quartz substrate; thinning the quartz substrate; metallizing the quartz substrate; providing a silicon base wafer; providing a diffraction grating to the silicon base wafer; metallizing the silicon base wafer; bonding the quartz substrate to the silicon base wafer and subsequently removing the silicon handle wafer, thereby producing a resonator; removing quartz from the resonator thus obtaining a modified resonator; providing a cap silicon wafer having a cavity etched therein; providing a vertical cavity surface emitting laser (VCSEL) on the cap wafer; providing an integrated beamsplitter and lens assembly to the top surface of the cap wafer; providing a lens to the top surface of the cap silicon wafer; providing a detector array on the cavity of the cap wafer; inverting the cap wafer, and bonding the inverted cap wafer to the modified resonator.

Further embodiments are disclosed throughout the specification, drawings and claims of the present disclosure.

### BRIEF DESCRIPTION OF THE DRAWINGS

FIG. 1 shows a schematic of the prior art, wherein wet chemistry (detection antibody) (75) applied to a specific region (70) adjacent to the upper tuning pad (15) and electrode (10) on the surface of a nanoresonator (79) wherein the detection of the cognate antigen (78) is then amplified by application of a capture antibody that is complexed with a metal nanoparticle (nanotag).

FIG. 2 shows a schematic of a sensor (135) according to the present disclosure for integrated simultaneous mass-added measurements and SERS analysis.

FIG. 3 shows a graph of the results from a nanoresonator of the present disclosure showing mass added data and SERS data from the same nanoresonator.

FIGS. 4A-4Q show a step-by-step assembly for sensor integration onto a wafer quartz chip.

### DETAILED DESCRIPTION

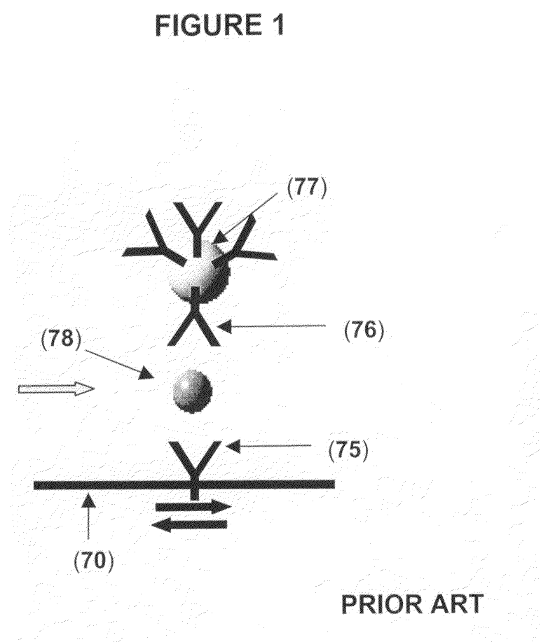

FIG. 1 shows a depiction of an antibody (75) that has been applied to a specific region (70) of a nanoresonator and a cognate antigen to be analyzed, along with a gold nanoparticle which is complexed with cognate capture antibodies. The capture antibodies, in complex with the gold nanoparticle, enhances the sensitivity of the mass spectroscopy of the nanoresonator. With the addition of SERS onto this chip an added mode of detection is provided to the sensor. The addition of SERS at this level is further disclosed herein.

Gold (Au) nanoparticles, also referred to as nanotags, provide increased mass as well as SERS sensitivity. Attachment of the nanoparticles for Raman signal amplification has been previously described in U.S. Pat. No. 6,514,767 to Natan, which is incorporated herein by reference in its entirety. The methodology for achieving attachment of the nanoparticles to antibodies for Raman signal amplification is also disclosed in this same U.S. patent to Natan. SERS chemistry with Au nanoparticles as described in Natan (U.S. Pat. No. 6,514,767) is incorporated herein by reference in its entirety.

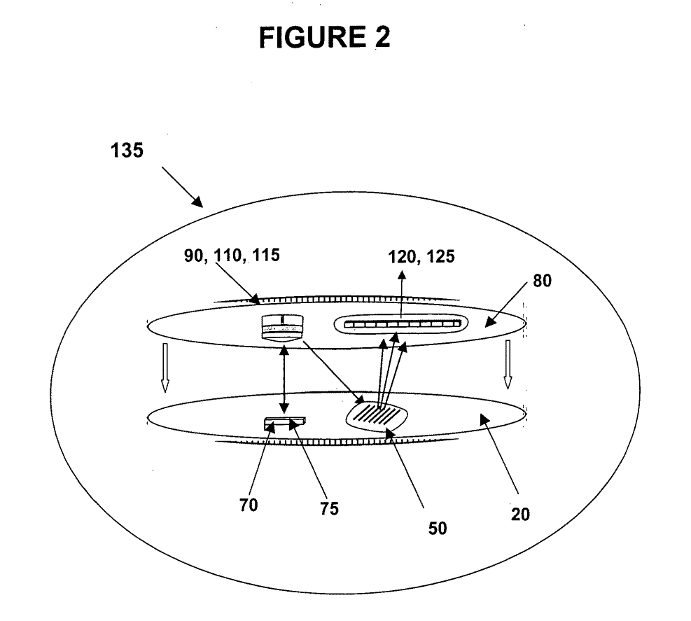

FIG. 2 shows an overview schematic of the sensor apparatus (135) of the present disclosure as further described herein. For detection of a species, an antigen of said species will bind to corresponding detection antibodies (75) applied to a specific region (70) of the nanoresonator. The high selectivity of the nanoresonator is accomplished by coating a quartz nanoresonator with sandwich amino assays. In one embodiment, the amino assays have enhanced sensitivity with gold nanoparticles attached to the capture antibody. In this way, the binding of an antigen (molecule of interest) to the detection antibody is added mass, providing a shift in resonant frequency of the nanoresonator.

After the sensor has been exposed to an environment for antigen capture, the sensor is then provided with capture antibodies which are preferably complexed to metal nanoparticles. These capture antibodies then complex with the antigen complexed to the detection antibodies and a larger (detection antibody-antigen-capture antibody) complex is formed on the region (70) of the sensor. This complex is then analyzed by mass spectroscopy as disclosed for such a quartz nanoresonator in Kubena (U.S. Ser. No. 10/426,931). The complex is simultaneously analyzed by the integrated SERS components (e.g. VSCEL (90), diffraction grating (50), and detector array (120) said integration being further described herein.

A sensor apparatus of the present disclosure can be used in both a gas and liquid environment. Such a sensor can be used to detect species in solution as well as those found in the air or any gaseous environment.

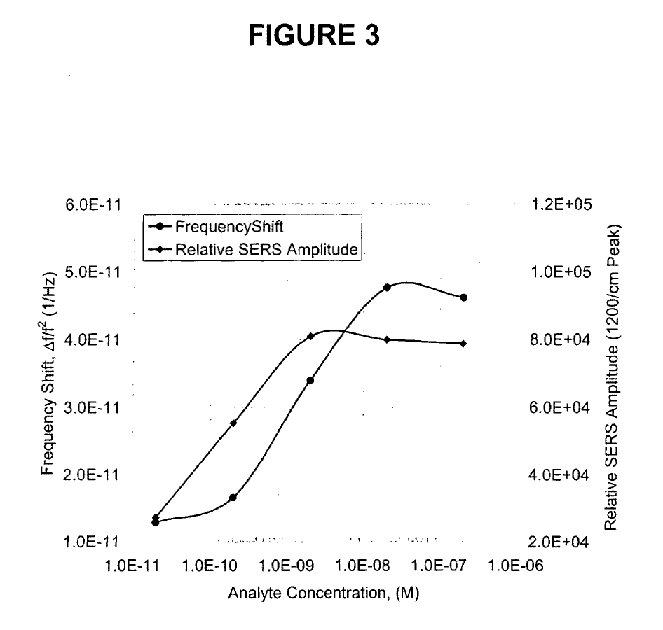

FIG. 3 shows mass detection data and SERS data and the correlation of both sets of data over a wide sensitivity range are acquired on one quartz nanoresonator.

The methodology for achieving the detection of amino assays at the chip (microscale) level is employed by micromachined resonators coated with detection antibodies is disclosed in the related U.S. Pat. No. 6,933,164 to Kubena, which is incorporated herein by reference in its entirety. The incorporation of SERS onto the chip (nanoresonator) is disclosed herein.

A sensor according to the present disclosure provides SERS analysis on a cavity (e.g. chip wafer) along with the antibody detection, for an on-chip detection sensor that is both highly selective and sensitive as well as being compact, lightweight, and disposable. To the applicants' knowledge this is the first biological sensor comprising SERS functionality and biological antibody detection using resonant frequency shifts at the microscale chip level.

A sensor according to the present disclosure comprises an optically integrated SERS present on the surface of a nanoresonator which has been fabricated for mass detection. The mass detection, which employs wet chemistry (e.g., antibodies) as it is applied to a quartz resonator is shown in FIG. 1. The detection antibody (75) is inherently specific to the required antigen detection, as is the capture antibody (76). The gold nanoparticles (77) have bonds specific for attachment to the capture antibody. Thus, once a species is detected, a resonant frequency shift is induced that is proportional to the mass of the attached antibody nanoparticle complexed to the antigen species. A resonator of the present disclosure is rugged and can withstand the chemical processing with no deleterious effects. The resonator has been disclosed in the related U.S. Pat. No. 6,933,164 to Kubena and U.S. patent application Ser. No. 10/426,931 to Kubena both of which are incorporated herein by reference in their entirety.

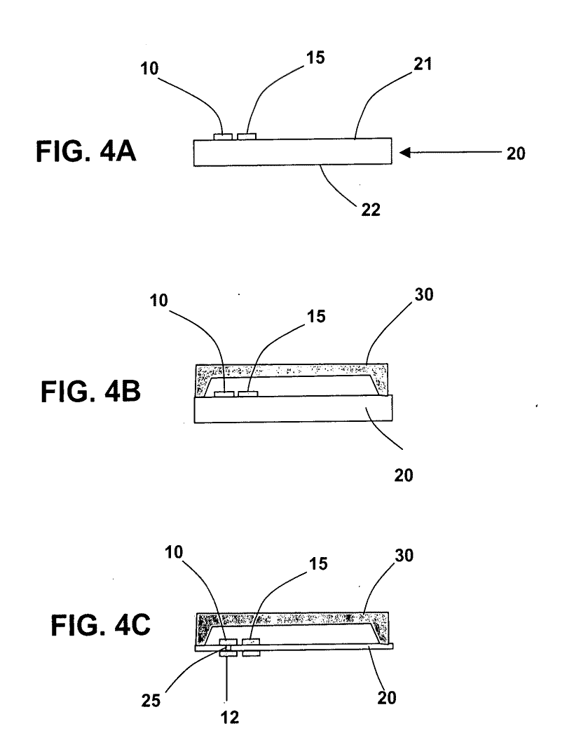

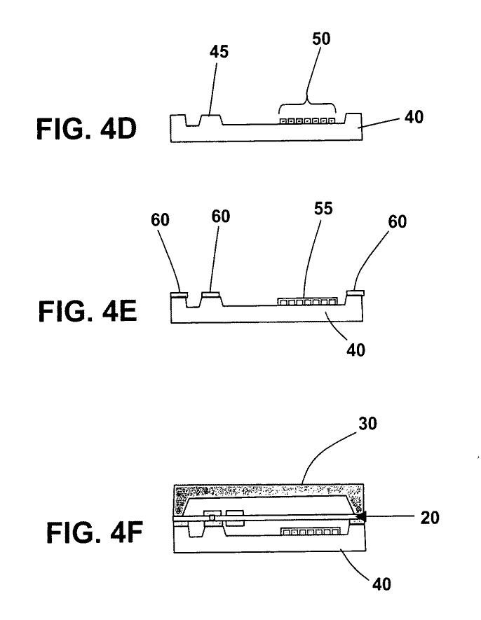

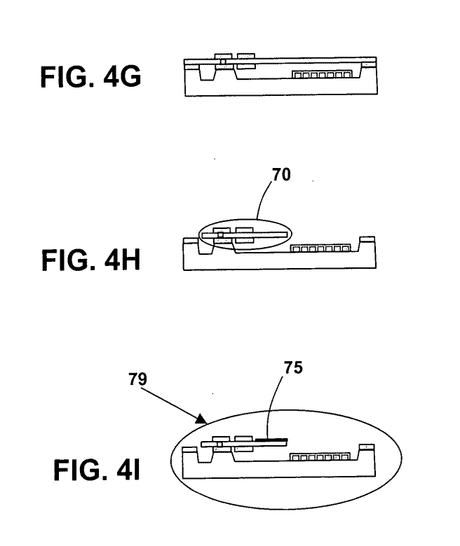

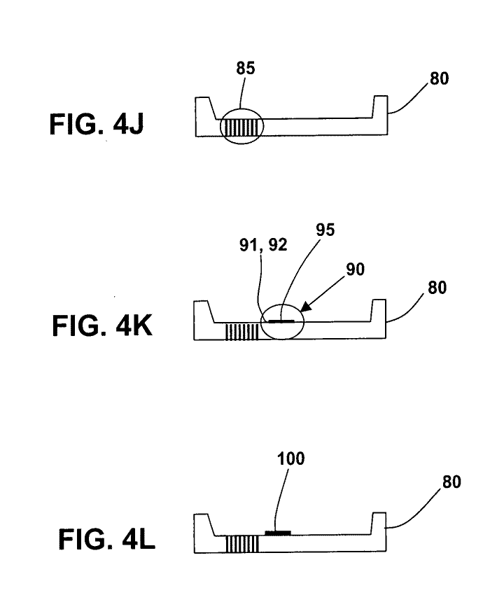

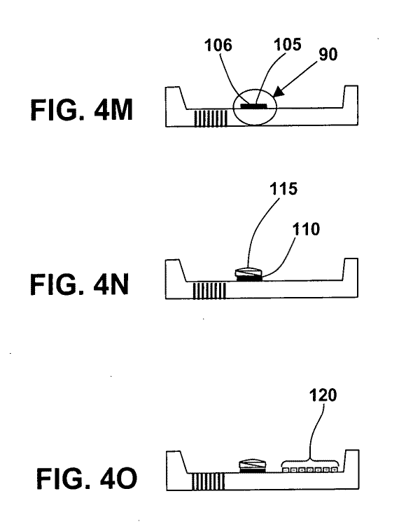

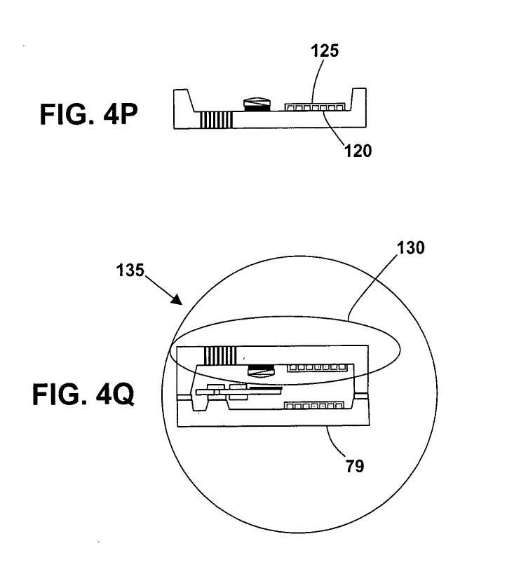

A method of sensing biological agents utilized by the resonator of the present disclosure, is carried out using an optically integrated SERS present on the surface of the nanoresonator. The method for integrating the optics with mechanical sensor is shown in the drawing of FIGS. 4A-4Q and described in Example 1. For integration, a resonator is prepared for simultaneous measurements of mass added and optical SERS analysis. A mechanical resonator structure that is of the nano or micro scale can be used. This nano or micro resonator is coated with a SOA bio assay detection film (FIG. 1). For example, one carrying out the present disclosure could use a quartz nanoresonator offering high Q, good thermal stability, low stiction (static friction) and no squeeze film damping as disclosed herein.

For optical sensing, a diode laser beam (90) illuminates the surface of a resonator and provides excitation for the SERS signal. Reflected light is directed, via a beam-splitter (110), to a periodic (diffraction) grating (50) for wavelength separation. A thin film dichroic filter (55) covers the grating (50) for the purpose of laser line rejection. Wavelength separated light collected by a linear detector array (120) is monitored for intensity versus wavelength. The detector array (120) is coated with a holographic filter (125) for rejection of Rayleigh scattering (unshifted light). A surface enhanced Raman signal which is characteristic of the antigen is detected, and the amplitude of it is dependent on the concentration of the bio species present. The SERS effect of a particular bio agent is known apriori and the observed discrete wavelength signals are compared against the known SERS effect of the bio agent.

In parallel with the SERS detection, a resonator (e.g., quartz nanoresonator) is driven at resonance and, as mass is added to the surface via the gold nanotags (nanoparticles) (77), a resonant frequency shift is observed. Results from simultaneous collection of mass added data and SERS data on a single quartz nanoresonator are shown in FIG. 3. FIG. 3 shows that the two sets of data are well correlated showing a df/f² 5×10⁻¹¹ Hz⁻¹ at the peak concentration of 9×10⁻⁷ M. The corresponding relative SERS amplitude is 8.0×10⁴ (for the 1200/cm peak). The ultimate sensitivity of the method disclosed herein is in the 100s of femto-molar concentration.

In one embodiment of the present disclosure, the sensor apparatus (FIG. 4A-4Q) is fabricated in a cavity. This cavity can be defined by two wafers—a base wafer (20) containing a quartz resonator, and a cap wafer (80) containing a NIR (near infra red) laser diode (90). Once the two wafers are processed and attached, they form an optical cavity containing the quartz sensing element (see Example 1, FIGS. 4A-4Q). As mentioned, the fabrication of the quartz resonator is described in U.S. patent application Ser. No. 10/426,931 to Kubena, and the chemistry of the capture and the SERS of nano-tags is described in U.S. Pat. No. 6,514,767 to Natan.

In an embodiment of the present disclosure (FIG. 2), a resonator (e.g., quartz nanoresonator) (79) is subjected to wet chemistry to generate a coating of detection antibodies (75). A lithographically formed diffraction grating (50) coated with a thin film dichroic filter (55) for laser line rejection forms the optical components on the base wafer (20). The selectivity of the coating process allows for the antibodies (75) to only attach to the resonator region (70). An on-chip NIR (˜800 nm) laser diode (90) is fabricated in an etched cavity on a separate cap wafer (80). This component is coated with a thin film beam-splitter (110) and focusing lens (115) assembly. The cap wafer also includes a detector array (120) and holographic filter coating (125). When the cap (80) and base (20) wafers are aligned, and then attached, the antibody coating (75) on the surface of the resonator (70) is illuminated by the laser diode (90). The wavelength resolution provided by the lithographically formed diffraction grating (50), and as seen by the detector array (120), can be adjusted by changing the distance between the grating (50) and the detector array (120).

According to the present disclosure, all optical and mechanical components of the sensor are fabricated on-chip. In one embodiment, at least one microfluidic channel can be incorporated into the resonator to enable precise delivery of detection antibody (75), or any detection molecule.

In an alternative embodiment, the resonator surface (70) can be submerged into solution for delivery of detection antibodies (75).

In a further embodiment of the present disclosure, the NIR laser diode (90) is a VCSEL (Vertical Cavity Surface Emitting Laser) laser diode having a monolithic laser cavity, in which the emitted light leaves the device in a direction perpendicular to the chip surface. The laser cavity is formed by two semiconductor Bragg mirrors (95, 105). Between the mirrors, there is a gain region with several quantum wells and a total thickness of a few microns. The VCSEL is less costly to manufacture in quantity, is easier to use and more efficient than other edge-emitting diodes presently available.

A detector array (120) on the cap wafer is made by a process that enables for micron-scale precision patterning of optical thin film dichroic coatings on a thin single substrate. Thus, thin film layers can be achieved through the deposition of thin layers of material onto a substrate, by physical vapor deposition such as evaporative or sputtering, or by a chemical process such as chemical vapor deposition.

According to a further embodiment of the present disclosure, a holographic filter coating (125) is applied to the cap wafer of the resonator. A holographic filter contains several layers, and all the layers are recorded simultaneously within a thick stack, such that the optical density of the notch filter is high and its spectral bandwith can be extremely narrow.

Further, since the layering profile is sinusoidal instead of squarewave, holographic notch filters are free from extraneous reflection bands and provide significantly higher laser damage thresholds. A holographic filter as described can be fabricated by Kaiser Optical Systems, Inc.

In an application of the present disclosure, a sensor according to the present disclosure is exposed to the capture antibody (76) solution subsequent to its exposure to the environment to be analyzed. In this way, the resonator is coated with nano-gold particles (77) wherever the antigen (78) is posited (FIG. 1). Given the smallness and thinness of the resonator, the resonator can be exposed to a series of small volume solutions. Alternatively, microfluidic channels can be integrated into the resonator to further reduce the volume required for the analytes.

### Example

### Chip Integration Process (FIGS. 4A-4Q)

FIG. 4A. A quartz substrate wafer (20) is provided comprising metal pattern formation including a first electrode (10) and first tuning pad (15). The quartz substrate comprises a first surface (21) and a second surface (22).

FIG. 4B. A silicon wafer (30) is provided in which a cavity is formed, creating a cavity to produce a silicon handle wafer which is then bonded to the first surface (21) of the quartz wafer (20).

FIG. 4C. The quartz wafer is thinned to the requisite resonator width (less than 10 micrometers). A via (25) is formed and metallized in the quartz wafer between a first electrode (10) positioned on the first surface (21) and a second electrode (12) positioned on the second surface (22). The quartz wafer is metallized and patterned for bond pads.

FIG. 4D. A silicon base wafer (40) is provided wherein a lithographically etched mesa (45) and lithographically etched diffraction grating (50) are formed within.

FIG. 4E. The diffraction grating (50) is coated with a dichroic filter (55) by layering thin films having varying refractive indices and thickness. The bond region is then subsequently metallized (60).

FIG. 4F. The upper silicon handle wafer (30) is bonded to the first surface of the quartz wafer (21) and the second surface of the quartz wafer (22) is bonded to the bottom silicon wafer (40).

FIG. 4G. The upper silicon handle wafer (30) is then removed.

FIG. 4H. The resonator region (70) is protectively masked and all quartz except that of the masked regions is removed, thereby producing a quartz resonator (79).

FIG. 4I. An active bio layer (75) (e.g. detection antibody) is deposited onto the surface of the resonator region (70).

FIG. 4J. A cap silicon wafer (80) is provided in which a cavity is formed, through which at least one via (85) is formed for exposure to antigen and capture antibody (76).

FIG. 4K. A laser diode: Vertical Cavity Surface Emitting Laser (VCSEL) (90) is then partially formed on the cap wafer (80). Lower metal contact (91) and n-type substrate (92) is deposited. On top of VCSEL a lower distributed Bragg reflector (DBR) (95) is deposited by layering materials of varying refractive indices. The thickness of these layers is lambda/4.

FIG. 4L. Active layer of VCSEL is formed by forming one or more quantum wells (QWs) by layering the quantum wells and quantum well barrier materials. The stack of quantum wells (100) are bounded by a confinement layer on either outer edge.

FIG. 4M. An upper (DBR) (105) and upper metal contact (106) to complete the VCSEL are formed in the cap silicon wafer (80).

FIG. 4N. An integrated beamsplitter assembly (110) is added to the cap wafer and a lens (115) is formed on the top surface.

FIG. 4O. A detector array (120) is formed on cavity floor of cap silicon wafer (80).

FIG. 4P. The detector array is coated with holographically formed filter (125) for rejection of Rayleigh scattering (unshifted light).

FIG. 4Q. The assembled cap wafer (130) is then inverted and bonded to the cap wafer resonator assembly (79) resulting in a mass detector and an optical Surface Enhanced Raman Spectroscopy (SERS) detector integrated onto a chip (135).

Let it be understood that the foregoing description is only illustrative of the invention. Various alternatives and modifications can be devised by those skilled in the art without departing from the spirit of the invention. Specifically, the wafers could be made of material other than silicon. Accordingly, the present invention is intended to embrace all such alternatives, modifications, and variances which fall within the scope of the appended claims. Additionally, whenever multiple steps are recited in a claim, it is intended that the order of some or all of the steps can be different from the order shown in the claim

1. An apparatus comprising:
a mass detector disposed within a cavity to detect a sample; and
an optical Surface Enhanced Raman Spectroscopy (SERS) detector disposed within said cavity to detect said sample.

2. The apparatus of claim 1, further comprising two wafers disposed to define the cavity therebetween.

3. The apparatus of claim 1, wherein the mass detector is a quartz resonator.

4. The apparatus of claim 1, wherein the mass detector is formed from a quartz substrate comprising a first surface and a second surface; the quartz substrate further comprising
at least a first and second electrode;
at least one tuning pad;
at least one via, and
a diffraction grating coated with a dichroic filter,
wherein the first electrode is on the first surface and the second electrode is on the second surface, and the at least one via connects the first electrode and the second electrode.

5. The apparatus of claim 1, wherein the optical SERS detector comprises:
a vertical cavity surface emitting laser (VCSEL), wherein the VCSEL comprises:
a lower metal contact;
a first distributed Bragg reflector (DBR);
an active layer comprised of one or more quantum wells;
a second DBR and an upper metal contact;
the apparatus further comprising:
an integrated beamsplitter and lens assembly coated with dichroic filter, wherein the dichroic filter is comprised of thin films of varying refractive indices;
a diffraction grating, and
a detector array coated with a holographically formed filter.

6. The apparatus of claim 5, wherein the VCSEL further comprises an n-type substrate.

7. The apparatus of claim 1, further comprising microfluidic channels connected to the mass detector for delivery of detection molecules.

8. A method for fabricating the apparatus of claim 1 comprising:
providing a first cavity and a second cavity;
providing a mass detector to the first cavity, and
providing an optical SERS detector to the first and second cavity.

9. A method for fabricating a sensor comprising the steps of:
providing a quartz substrate;
providing at least one electrode and at least one tuning pad to the quartz substrate;
providing a silicon handle wafer having a cavity etched therein;
bonding the silicon handle wafer to the quartz substrate;
thinning the quartz substrate;
metallizing the quartz substrate;
providing a silicon base wafer;
providing a diffraction grating to the silicon base wafer;
metallizing the silicon base wafer;
bonding the quartz substrate to the silicon base wafer and subsequently removing the silicon handle wafer, thereby producing a resonator;
removing quartz from the resonator thus obtaining a modified resonator;
providing a cap silicon wafer having a cavity etched therein;
providing a vertical cavity surface emitting laser (VCSEL) on the cap wafer;
providing an integrated beamsplitter and lens assembly to the top surface of the cap wafer;
providing a lens to the top surface of the cap silicon wafer;
providing a detector array on the cavity of the cap wafer;
inverting the cap wafer, and
bonding the inverted cap wafer to the modified resonator.

10. The method of claim 9, wherein the quartz substrate comprises a first surface and a second surface;
wherein the at least one electrode comprises a first electrode and a second electrode;
the first electrode is positioned on the first surface of the quartz substrate and the second electrode is positioned on the second surface of the quartz substrate, and
the quartz substrate further comprises at least one via, wherein the least one via connects the first electrode to the second electrode.

11. The method of claim 10, wherein the silicon handle wafer is bonded to the first surface of the quartz substrate.

12. The method of claim 10, wherein the second surface of the quartz substrate is bonded to the silicon base wafer.

13. The method of claim 9, further comprising the step of coating said diffraction grating with a dichroic filter.

14. The method of claim 9, further comprising the step of providing at least one via through the cavity of the cap silicon wafer.

15. The method of claim 9, further comprising the step of providing a holographically formed filter coat to the detector array.

16. The method of claim 9 further comprising the step of coating the modified resonator with antibodies.

17. The method of claim 16, wherein the antibodies are provided by way of at least one microfluidic channel.

18. The method of claim 16, wherein the antibodies are provided by submerging the modified resonator into solution.

19. The apparatus of claim 1 for use in detecting biological species.

20. The apparatus made by the method of claim 9 for use in detecting biological species.
